(19) United States
(12) Patent Application Publication
(10) Pub. No.: US 2008/0156636 A1
(43) Pub. Date: Jul. 3, 2008

(54) Homogeneous Copper Interconnects for BEOL

(75) Inventors: Kevin S. Petrarca, Newburgh, NY (US); Mahadevaiyer Krishnan, Hopewell Junction, NY (US); Michael Lofaro, Hopewell Junction, NY (US); Kenneth P. Rodbell, Sandy Hook, CT (US)

Correspondence Address: INTERNATIONAL BUSINESS MACHINES CORPORATION;DEPT. 18G, BLDG. 300-482, 2070 ROUTE 52, HOPEWELL JUNCTION, NY, 12533, US

(73) Assignee: INTERNATIONAL BUSINESS MACHINES CORPORATION, Armonk, NY (US)

(21) Appl. No.: 11/971,488

(22) Filed: Jan. 9, 2008

Related U.S. Application Data
(62) Division of application No. 10/711,700, filed on Sep. 30, 2004.

(51) Int. Cl. C23C 14/16

(52) U.S. Cl. 204/192.1; 205/123

(57) ABSTRACT

Defects on the edge of copper interconnects for back end of the line semiconductor devices are alleviated by an interconnect that comprises an impure copper seed layer. The impure copper seed layer covers a barrier layer, which covers an insulating layer that has an opening. Electroplated copper fills the opening in the insulating layer. Through a chemical mechanical polish, the barrier layer, the impure an impure copper seed layer derived from an electroplated copper bath copper seed layer, and the electroplated copper are planarized to the insulating layer.

This application is a divisional of U.S. patent application Ser. No. 10/711,700, attorney docket number FIS920040258US1, filed on Sep. 30, 2004.

### FIELD OF THE INVENTION

The present invention relates generally to semiconductor devices and more particularly to copper interconnects used in back end of the line semiconductor structures.

### BACKGROUND OF THE INVENTION

Semiconductor chips comprise a series of devices. The devices are connected to a silicon base layer below and connected to a stack of wiring layers above, i.e. interconnect layers or interconnects. The interconnects connect the devices in the silicon base layer. Interconnect layers alternate with one layer of pin-line connections, i.e. holes or vias, and a second layer of wiring connections, i.e. lines. Dual damascene, which is the most common interconnect creation technique, refers to a process by which two structures, i.e. a via and a trench, are filled with a conductor at the same time. The dual damascene method saves steps, and consequently, costs.

Copper interconnects, formed in accordance with the dual damascene method, are widely used in the back end of the line (“BEOL”) semiconductor structures. Vias and trenches are etched into an insulating layer. Then, prior to the deposition of any copper, a barrier layer is placed on the insulating layer. Because copper can diffuse down through the insulating layer to the silicon layer, which is problematic because copper adversely affects the conductance of silicon, a barrier layer is deposited atop the etched insulating layer. The barrier layer also adheres the seed layer and the insulating layer. Further details regarding the barrier layer can be found in U.S. Pat. Nos. 6,709,562, 6,380,628, 6,339,258, and 6,337,151, which are incorporated herein by reference in their entirety. Upon the barrier layer, a pure copper seed layer is deposited. The pure copper seed layer facilitates copper nucleation from the electroplated copper. Electroplated copper from an electroplate copper bath then fills the via and the trench. Afterwards, a chemical mechanical polish (“CMP”) removes extraneous copper and planarizes the copper interconnect. Unlike the seed layer, the electroplated copper bath comprises impure copper.

FIG. 1 depicts an etched feature comprising a trench 110 and via 120 etched into an insulating layer 115, e.g. a dielectric, using dual damascene. FIG. 2 depicts an incomplete prior art interconnect formed with a pure copper seed layer 240. FIG. 3 depicts a complete prior art interconnect with the addition of electroplated copper 350 that fills trench and via and that through CMP has been planarized to the insulating layer. In FIG. 3, it is clear that the composition of the seed layer 240 and the electroplated copper 350 that fills the trench and via is different in the prior art interconnect. More specifically, the seed layer 240 comprises pure copper, while the electroplated copper 350 comprises impurities. Historically, a pure copper seed layer was used because pure copper was known to be more conductive than aluminum. However, the defects associated with the prior art interconnect are clearly depicted in FIG. 3a, which will be discussed herein below in further detail.

As mentioned above, the prior art technique utilizes a pure copper seed layer. In the industry, such copper is typically 99.999% pure. Impure copper has a larger grain size than pure copper, accordingly, impure copper is less resistive and more conductive than pure copper, which creates a faster copper interconnect. During CMP, pure copper polishes at a slower rate than impure copper. Even more problematic than the rate of CMP, however is that pure copper allows the creation of defects along the edge of the interconnect, which is made during CMP. More specifically, protrusions result in the pure copper seed layer, i.e. dendritic formation, and the edges of the interconnect erode during CMP. The eroded interconnect edge is clearly depicted in FIG. 3a.

FIG. 3a depicts an exploded view of the prior art copper interconnect edge shown in FIG. 3. As shown in FIG. 3a, the use of a pure copper seed layer lends to erosion of the prior art interconnect. The erosion 390 begins in the pure copper seed layer 240 and extends into the electroplated copper 350 of the prior art interconnect. The erosion is clearly depicted in FIG. 3a. Besides edge erosion 390, FIG. 3a also highlights another defect associated with prior art copper interconnects, namely dendritic formation. On the edge of the pure copper seed layer protusions form, which are known as dendrites 395. Both interconnect edge erosion and dendritic formation are problems associated with prior art copper interconnects.

What is needed in the art is a copper interconnect that neither erodes nor enables the creation of dendrites during CMP.

### SUMMARY OF THE INVENTION

The present invention is directed to a copper interconnect that comprises an impure copper seed layer. The impure copper seed layer is derived from an electroplated copper bath that is deposited on a barrier layer. The barrier layer prevents substantial diffusion of copper through to an underlying insulating layer. An impure copper that is derived from an electroplated copper bath then fills an opening in the insulating layer.

Due to the presence of an impure copper seed layer, the present invention creates a copper interconnect that has the same cross sectional area as prior art interconnects, but alleviates the defects of edge erosion and dendritic formation. Another advantage of the present invention is that the copper interconnect of the present invention is more conductive than prior art interconnects without alteration of interconnect fabrication processes already in place.

### BRIEF DESCRIPTION OF THE FIGURES

The features and the elements characteristic of the invention are set forth with particularity in the appended claims. The drawings are for illustration purposes only and are not drawn to scale. Furthermore, like numbers represent like features in the drawings. The invention itself, however, both as to organization and method of operation, may best be understood by reference to the detailed description which follows, taken in conjunction with the accompanying drawings, in which:

FIG. 1 depicts an etched feature comprising of a trench 110 and via 120 in an insulating layer 115;

FIG. 2 depicts an incomplete interconnect formed with a barrier layer 230 and a pure copper seed layer 240 which have been added to the etched feature of FIG. 1 in accordance with the prior art method;

FIG. 3 depicts a completed prior art interconnect with the addition of electroplated copper 350 to the incomplete interconnect of FIG. 2;

FIG. 3a depicts an exploded view of the edge of the completed prior art interconnect of FIG. 3.

FIG. 4 depicts an incomplete interconnect formed with a barrier layer 430 and an impure copper seed layer 440 in accordance with the present invention;

FIG. 5 depicts a completed interconnect with the addition of electroplated copper 350 to the incomplete interconnect of FIG. 4 formed in accordance with the present invention; and,

FIG. 5a depicts an exploded view of the edge of the completed interconnect of FIG. 5 formed in accordance with the present invention.

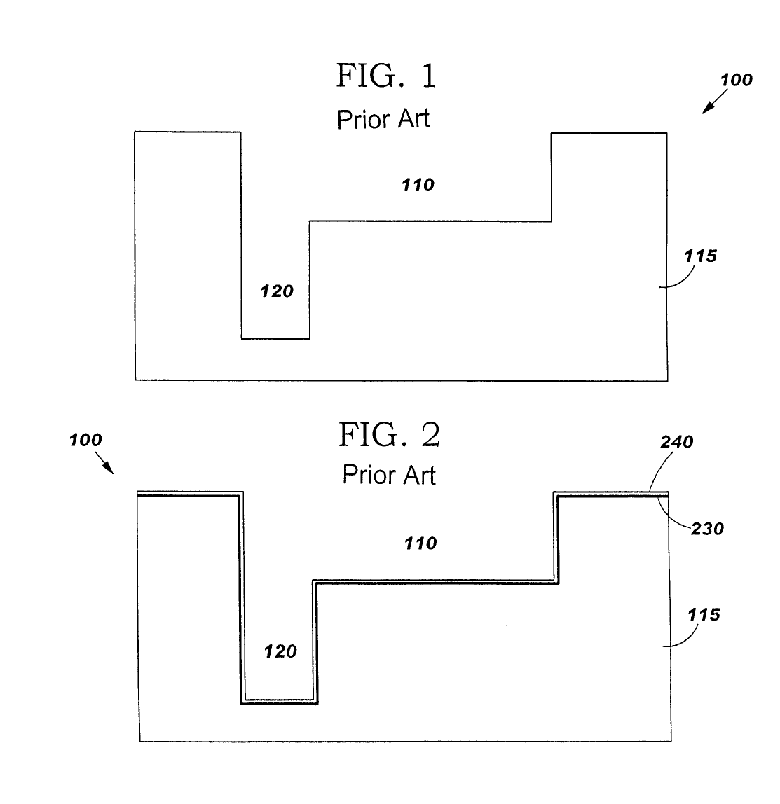

The invention will now be described by reference to the accompanying figures. In the figures, various aspects of the structures have been shown and schematically represented in a simplified manner to more clearly describe and illustrate the invention.

### DETAILED DESCRIPTION OF THE PREFERRED EMBODIMENTS

By way of overview and explanation, the present invention discloses the utilization of an impure copper seed layer with substantially the same composition as the electroplated copper in the completed copper interconnect. Both the impure copper for the impure copper seed layer and the electroplated copper are derived from an impure copper seed source, i.e.. target, with an impurity content of not more than 1.20% by weight and not less than or equal to 0.001% by weight or in other mathematical words, 0.001%>impurity content≦1.20%. Such impure copper sources are generally well known in the art. Deposition of the seed layer affects the trace elements, i.e. impurities, in the impure copper. For example, one method of deposition for the seed layer is known as sputtering. The impurities in the impure copper seed layer will not sputter exactly as the impurities in the electroplate copper bath electroplate. Accordingly, the composition of the copper in the impure copper seed layer and the electroplated copper will be slightly different. While sputtering is one method of impure copper layer deposition, other methods may include physical vapor deposition (“PVD”), chemical vapor deposition (“CVD”), ionized physical vapor deposition (“IPVD”), and atomic layer deposition (“ALD”). PVD includes, but is not limited to, various evaporation and sputtering techniques such as DC or RF plasma sputtering, bias sputtering, magnetron sputtering, ion plating, or ionized metal plasma sputtering. CVD includes, but is not limited to, thermal CVD, plasma enhanced CVD, low pressure CVD, high pressure CVD, and metal organo CVD. In sum, deposition affects the composition of the impure copper. The composition of the impure copper seed layer and the electroplated copper, however, remains substantially similar because the copper in the impure copper seed layer and the electroplated copper are both derived from a source with an impurity content of not more than 1.20% by weight and not less than or equal to 0.001% by weight.

Electroplated copper has a myriad of impurities comprised mainly of metals and organic materials. Some such impurities include, but are not limited to, Ag, As, C, Cd, Cl, Co, Cr, Fe, In, Mg, Mn, N, Ni, O, Pb, S, Sn, Tl, and Zn. Such impurities enhance the interconnect because the impurities reduce the resistivity of the interconnect.

The preferred method for formation of a copper seed layer of substantially the same composition as the electroplated copper comprises using an impure copper target and depositing the target material on the barrier layer, which is accomplished by electroplating the target with the same type of copper plating bath that is used to fill the BEOL interconnects. As mentioned above, the barrier layer prevents diffusion of the copper through to the insulating layer. Alternately, a pure copper seed source could be forged with impurities, however this would need to be monitored carefully such that the forged copper does not become resistive.

An alternative embodiment of the present invention comprises a copper interconnect with an impure copper seed layer fill. In the first described embodiment of the present invention, upon a barrier layer an impure copper seed layer is deposited and an impure copper from the electroplated copper bath fills an opening in an insulating layer. By contrast, in such alternative embodiment of the present invention, upon a barrier layer an impure copper seed layer is deposited that fills the opening in the insulating layer. Such alternative embodiment eliminates the need for an impure copper derived from an electroplated copper bath that fills the opening in the insulating layer. Instead, the impure copper seed layer fills the opening in the insulating layer.

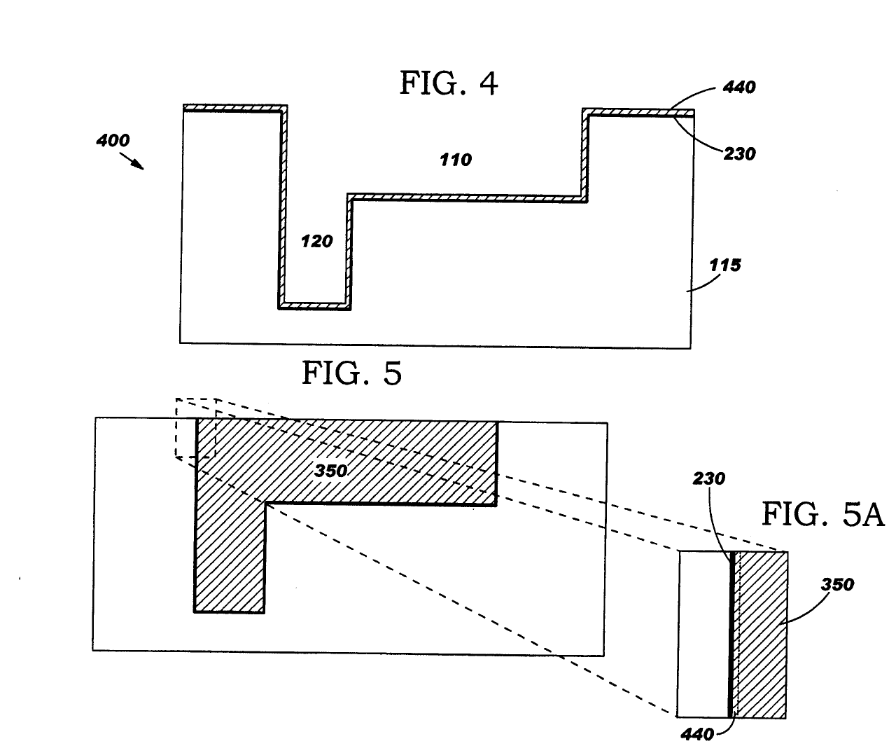

FIG. 4 depicts an incomplete copper interconnect formed in accordance with the present invention. The incomplete copper interconnect of FIG. 4 comprises an impure copper seed layer 440. FIG. 5 depicts a completed copper interconnect formed in accordance with the present invention with the addition of electroplated copper 350 to the incomplete interconnect of FIG. 4. Prior to deposition, the composition of the copper in the impure copper seed layer 440 is substantially the same as the electroplated copper 350 because both are derived from a source with an impurity content of not more than 1.20% by weight and not less than or equal to 0.001% by weight. Deposition of the impure seed layer affects some of the impurities in the impure copper seed layer. Accordingly, after deposition some of the impurities in the electroplated copper 350 are no longer present in the impure copper seed layer 440. Consequently, the composition of the impure copper seed layer 440 and the electroplated copper 350 is substantially similar. As FIG. 5 depicts, the composition of the impure copper seed layer 440 is substantially similar to the composition of electroplated copper 350.

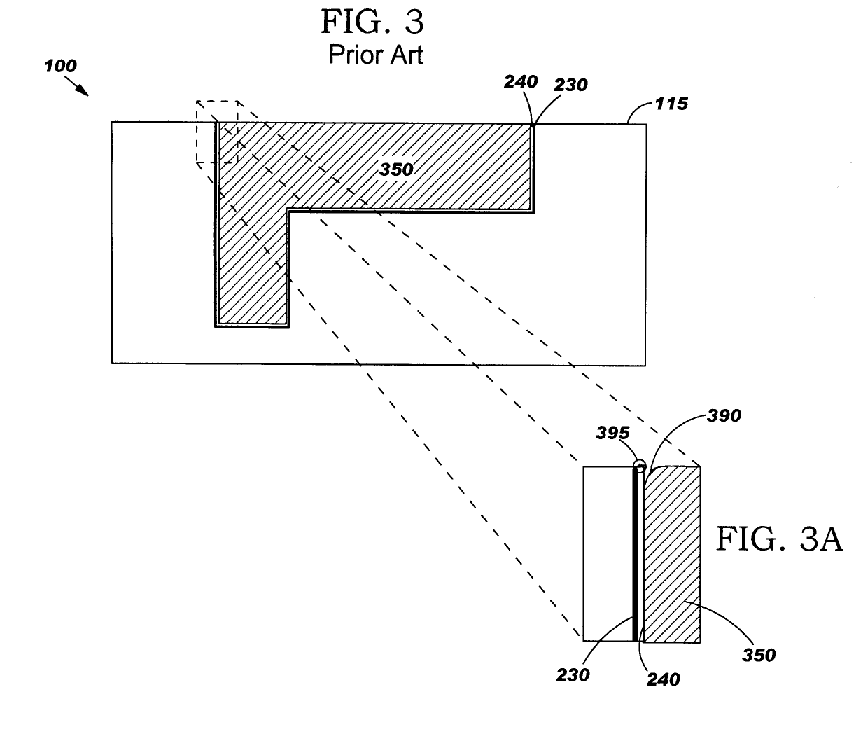

FIG. 5a depicts an exploded view of the edge of the completed copper interconnect of the present invention depicted in FIG. 5. As shown in FIG. 5a, the use of an impure copper seed layer reduces the edge erosion depicted in FIG. 3a. In addition, FIG. 5a also highlights that the use of an impure copper seed layer suppresses dendritic formation during CMP. Accordingly, FIG. 5a demonstrates that the copper interconnect of the present invention is a copper interconnect that alleviates erosion and dendritic formation during CMP.

While the present invention has been particularly described in conjunction with a specific preferred embodiment and alternative embodiments, it is evident that numerous alternatives, modifications and variations will be apparent to those skilled in the art in light of the foregoing description. It is therefore intended that the appended claims embrace all such alternatives, modifications and variations as falling within the true scope and spirit of the present invention.

What is claimed is:

1. A method for forming a copper interconnect, comprising the steps of:
depositing an impure copper seed layer derived from an impure copper seed source with a content of impurities on a barrier layer, said barrier layer prevents substantial diffusion of said copper through to an underlying insulating layer and lines an opening in said underlying insulating layer, and,
filling said opening with impure copper derived from an impure copper seed source with a content of impurities.

2. A method as in claim 1, wherein said copper source of said impure copper seed layer is equivalent to said copper source of said impure copper.

3. A method as in claim 1, wherein said impurity content comprises not more than 1.20% by weight and not less than or equal to 0.001% by weight of said at least one of said impure copper seed layer and said impure copper

4. A method as in claim 1, wherein said impure copper source comprises impurities chosen from the group of Ag, As, C, Cd, Cl, Co, Cr, Fe, In, Mg, Mn, N, Ni, O, Pb, S, Sn, Tl, and Zn.

5. A method as in claim 1, wherein prior to deposition, said impure copper in said impure copper seed layer is substantially equivalent to said impure copper.

6. A method as in claim 1, wherein said impure copper seed layer is deposited by at least one of sputtering, PVD, CVD, IPVD, and ALD.

7. A method as in claim 1, further comprising the step of:
chemical mechanically polishing said impure copper seed layer, said barrier layer, and said impure copper, until said impure copper seed layer, said barrier layer, and said impure copper are planarized to said insulating layer.

8. A method for forming a copper interconnect, comprising the steps of:
depositing an insulating layer;
etching an opening in said insulating layer;
depositing a barrier layer that prevents copper diffusion through to said insulating layer, which lines said opening, in said insulating layer; and,
filling said opening with impure copper seed derived from an impure copper seed source with a content of impurities.

9. A method as in claim 8, wherein said impurity content comprises not more than 1.20% by weight and not less than or equal to 0.001% by weight of said at least one of said impure copper seed.

10. A method as in claim 8, further comprising the step of:
chemical mechanically polishing said impure copper seed and said barrier layer until said barrier layer and said impure copper seed are planarized to said insulating layer.

11. A method as in claim 8, wherein said impure copper seed source comprises impurities chosen from the group of Ag, As, C, Cd, Cl, Co, Cr, Fe, In, Mg, Mn, N, Ni, 0, Pb, S, Sn, Tl, and Zn.

12. A method as in claim 8, wherein said impure copper seed is deposited by at least one of sputtering, PVD, CVD, IPVD, and ALD.
